(19) United States
(12) Patent Application Publication
(10) Pub. No.: US 2008/0032492 A1
(43) Pub. Date: Feb. 7, 2008

(54) METHOD OF MANUFACTURING FLASH MEMORY DEVICE

(76) Inventor: In-Cheol Baek, Daejeon (KR)

Correspondence Address: SHERR & NOURSE, PLLC, 620 HERNDON PARKWAY, SUITE 200, HERNDON, VA, 20170, US

(21) Appl. No.: 11/781,623

(22) Filed: Jul. 23, 2007

(30) Foreign Application Priority Data
Aug. 2, 2006 (KR) 10-2006-0072954

(51) Int. Cl. H01L 21/3205; H01L 29/788

(52) U.S. Cl. 438/595; 257/315; 257/E29.3; 257/E21.294

(57) ABSTRACT

A method of manufacturing a flash memory device including at least one of the following steps: Forming a poly-silicon layer on a semiconductor substrate. Forming a plurality of photo-resist patterns on the poly-silicon layer to be spaced apart from each other by a predetermined distance. Forming a spacer oxidation film on the photo-resist patterns. Forming spacers on respective side walls of the photo-resist patterns by etching the spacer oxidation film. Forming a plurality of poly-silicon layer patterns by etching the poly-silicon layer using the photo-resist patterns and the spacers as etching resist films. Removing the photo-resist patterns and the spacers that are formed on the poly-silicon layer patterns.

This application claims the benefit of Korean Patent Application No. P2006-0072954, filed on Aug. 2, 2006, which is hereby incorporated by reference in it's entirety.

### BACKGROUND

Flash memory is a kind of electrically rewritable programmable read-only-memory (PROM). Some flash memory includes Electrically Erasable Programmable Read Only Memory (EEPROM). Since information stored in flash memory does not vanish when power is off, flash memory may be considered a type of nonvolatile memory. Flash memory may be classified as either NOR type flash memory or NAND type flash memory. In NOR type flash memory, cells may be arranged in parallel between a bit line and ground. In NAND type flash memory, cells may be arranged in series between a bit line and ground. The parallel-structured NOR-type flash memory can perform a READ operation relatively quickly. Accordingly, NOR-type flash memory may be used to boot mobile phones relatively quickly. The serial-structure type NAND type flash memory can perform a WRITE operation relatively quickly. Accordingly, NAND type flash memory may be best suited for data storage applications.

Flash memory may be classified into stack gate type flash memory and split gate type flash memory according to the unit cell structure. Flash memory may be classified into floating gate devices and Silicon-Oxide-Nitride-Oxide-Silicon (SONOS) devices. Floating gate type devices may include a floating gate made of poly-crystal silicon and surrounded by an insulator. Charges may be injected into or discharged from the floating gate by means of a channel hot carrier injection or a fowler-Nordheim (F—N) tunneling to store and erase data.

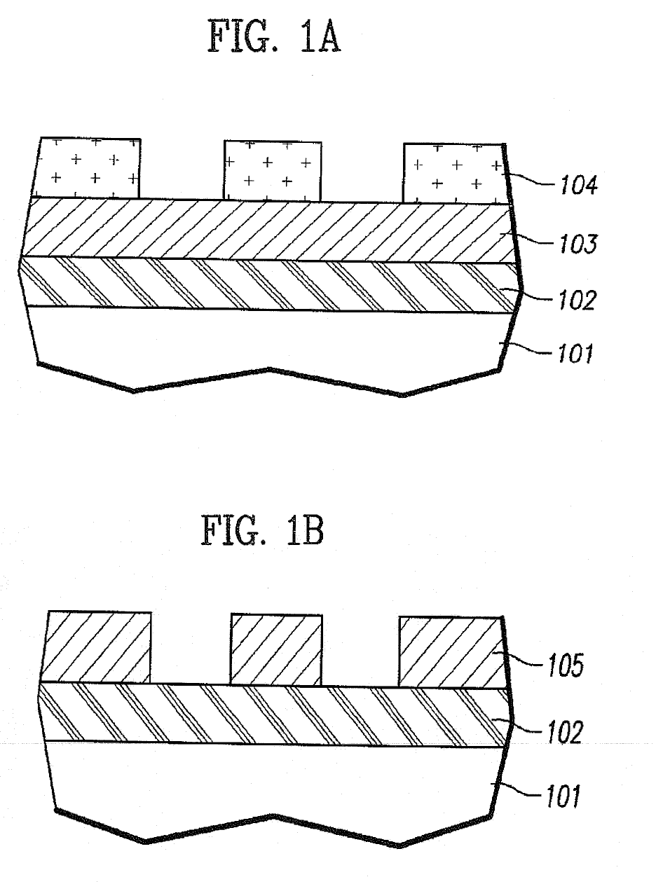

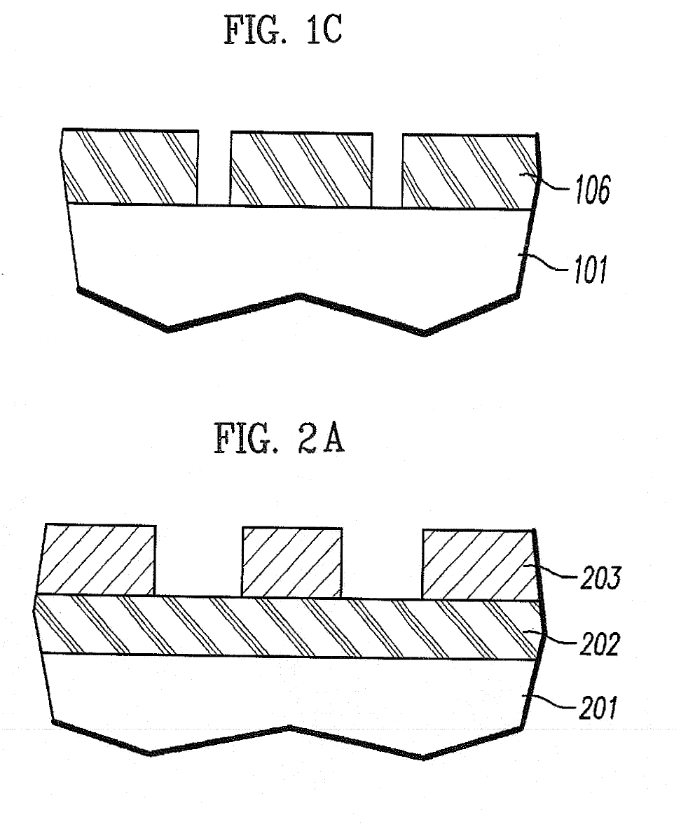

FIGS. 1A to 1C illustrate a method of forming a floating gate in a flash memory device. As illustrated in FIG. 1A, poly-silicon layer 102 and hard mask 103 may be sequentially formed over semiconductor substrate 101. A photo-resist film may be coated over hard mask 103 and the photo-resist film may be patterned to form a plurality of photo-resist patterns 104.

As illustrated in FIG. 1B, photo-resist patterns 104 are used as an etching resist film to etch hard mask 103 to form a plurality of hard mask patterns 105. Photo-resist patterns 104 over hard mask patterns 105 may be removed by ashing. Spacers (e.g. made of a Tetra-Ethyl-Ortho-Silicate (TEOS)) may be formed on side walls of hard mask patterns 105.

As illustrated in FIG. 1C, hard mask patterns 105 are used as the etching-resist film to etch poly-silicon layer 102 to form a plurality of poly-silicon layers 106. The spacers and hard mask patterns 105 may be removed to allow the floating gate of a flash memory device to be formed. A floating gate may be formed by several complicated processes such as photolithography, hard mask patterning, and forming spacers. These several complicated steps may result in a relatively low efficient yield and/or may not optimize productivity.

### SUMMARY

Embodiments relate to a method of forming a floating gate in a flash memory device using a spacer formed by atomic layer deposition. In embodiments, a method of manufacturing a flash memory device may be simplified to optimize productivity, yield, and manufacturing costs. In embodiments, a critical dimension (CD) of a floating gate may be precisely adjusted within several nanometers, which may maximize integration of a semiconductor device.

Embodiments relate to a method of manufacturing a flash memory device including at least one of the following steps: Forming a poly-silicon layer on a semiconductor substrate. Forming a plurality of photo-resist patterns on the poly-silicon layer to be spaced apart from each other by a predetermined distance. Forming a spacer oxidation film on the photo-resist patterns. Forming spacers on respective side walls of the photo-resist patterns by etching the spacer oxidation film. Forming a plurality of poly-silicon layer patterns by etching the poly-silicon layer using the photo-resist patterns and the spacers as etching resist films. Removing the photo-resist patterns and the spacers that are formed on the poly-silicon layer patterns.

### DRAWINGS

Example FIGS. 1A to 1C are sectional views illustrating a method of manufacturing a flash memory device.

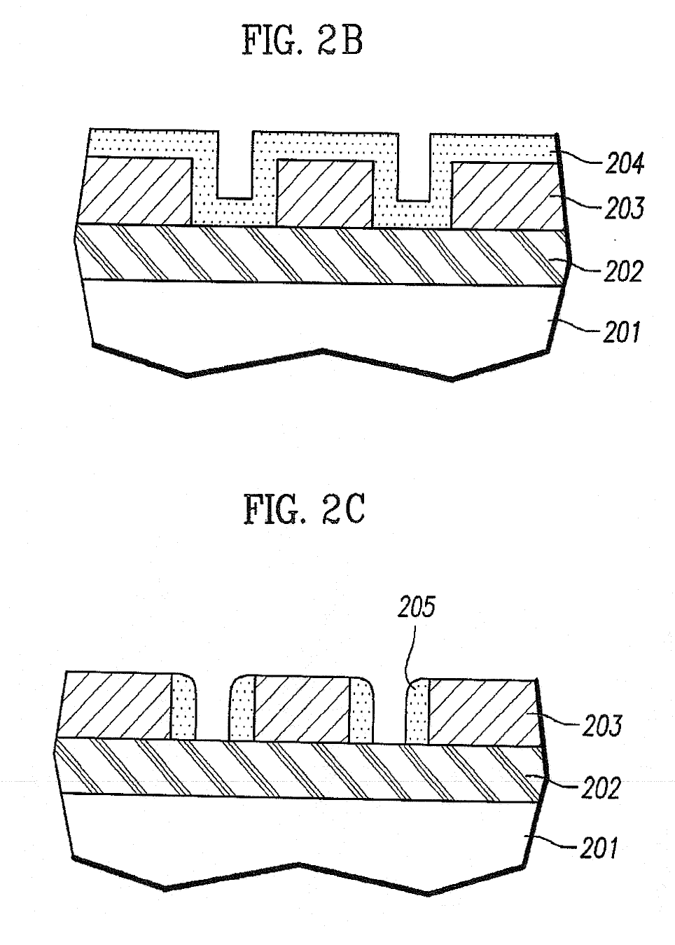

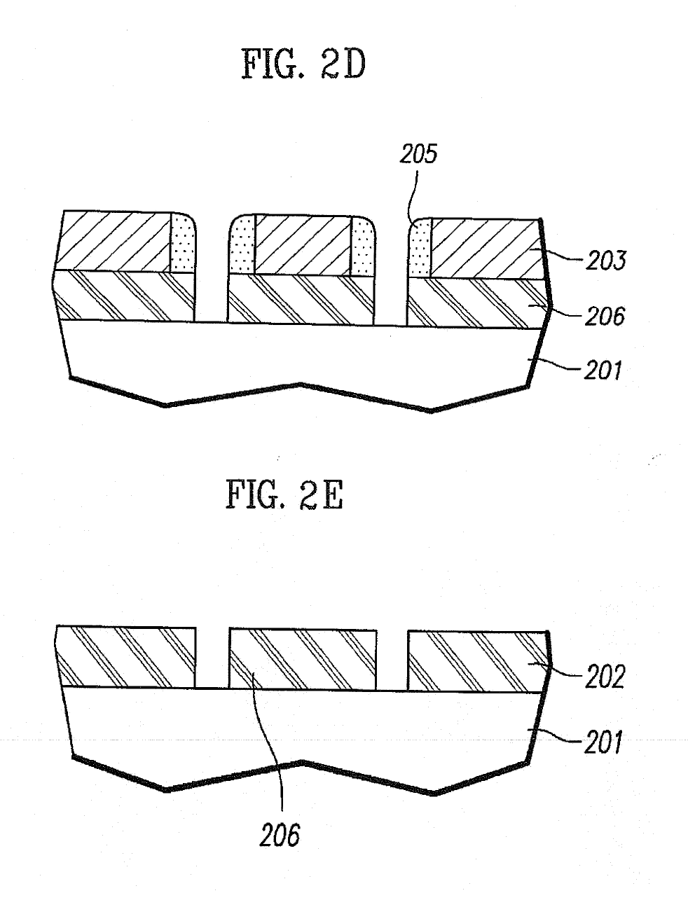

Example FIGS. 2A to 2E are sectional views illustrating a method of manufacturing a flash memory device, in accordance with embodiments.

### DESCRIPTION

As illustrated in example FIG. 2A, a poly-silicon layer 202 may be formed on and/or over a semiconductor substrate 201, in accordance with embodiments. A photoresist film may be formed (e.g. by coating) on and/or over poly-silicon layer 202. The photoresist film may be patterning (e.g. by photolithography and etching) to form a plurality of photo-resist patterns 203, which may be spaced apart from each other by a predetermined distance.

As illustrated in example FIG. 2B, a spacer oxidation film 204 may be formed on and/or over the surface of the photo-resist patterns 203, in accordance with embodiments. The spacer oxidation film 204 may be formed by atomic layer deposition (ALD). ALD is a deposition method capable of implementing relatively good step coverage with predicable results, so that predetermined step coverage may be formed regardless of the density of patterns or positions of the patterns. Accordingly, in embodiments, a uniform space oxidation film can be formed on the upper surface and side walls of photo-resist patterns 203. In embodiments, spacer oxidation film 204 may comprise at least one of Al₂O₃, SiO₂, and HfO₂ as an oxide material.

In embodiments, deposition using ALD may be performed at a relatively low temperature (e.g. approximately 100° C.). In embodiments, ALD may be performed at a temperature below approximately 100° C. or below approximately 120° C. In embodiments, by performing ALD at a relatively low temperature, peeling of the spacer oxidation film 204 from photoresist patterns 203 may be prevented.

As illustrated in example FIG. 2C, spacer oxidation film 204 may be etched (e.g. by a blank etch method) to form spacers 205 on side walls of the photo-resist patterns 203, in accordance with embodiments.

As illustrated in example FIG. 2D, photo-resist patterns 203 and spacers 205 may be used as etching resist layers to etch the poly-silicon layer 202, in accordance with embodiments. In embodiments, a plurality of poly-silicon layer patterns 206 may be formed. In embodiments, poly-silicon layer patterns 206 may be formed by reactive ion etching (RIE).

As illustrated in example FIG. 2E, after forming poly-silicon layer patterns 206, photo-resist patterns 203 and the spacers 205 may be removed, in accordance with embodiments. In embodiments, photo-resist patterns 203 and spacers 205 may be removed by ashing and/or cleansing.

In accordance with embodiments, a plurality of poly-silicon layer patterns 206 may be formed within a precise critical dimension (CD). CD may be equal to or less than approximately 90 nm, in accordance with embodiments. With a relatively small critical dimension that can be predictably formed, relatively high integration in flash memory device may be optimized, in accordance with embodiments.

According to embodiments, photo-resist patterns and spacers may be used as etching resist films for etching a poly-silicon layer to form poly-silicon layer patterns. In embodiments, during the manufacturing of the floating gate of the flash memory device and the spacers are directly formed on the surfaces of the photo-resist patterns by ALD. In embodiments where photo-resist patterns and the spacers are used as an etching resist films against the poly-silicon layer, a process may be simplified and/or productivity improved. In embodiments, spacers may be formed by ALD and used as etching resist films so that the precision of the critical dimensions of a floating gate can be optimally reproducible, which may result in optimized semiconductor processing.

It will be apparent to those skilled in the art that various modifications and variations can be made to embodiments without departing from the spirit or scope of the embodiments. Thus, it is intended that embodiments cover the modifications and variations of embodiments that fall within the scope of the appended claims and their equivalents.

What is claimed is:

1. A method comprising:
forming a poly-silicon layer over a semiconductor substrate;
forming a photo-resist layer over the poly-silicon layer;
patterning the photo-resist layer to form at least one opening in the photo-resist layer;
forming a spacer oxidation film over the patterned photo-resist layer and over sidewalls of said at least one opening in the photo-resist layer;
etching the spacer oxidation film to form spacers over the sidewalls; and
etching the poly-silicon layer using the spacers as an etch mask.

2. The method of claim 1, wherein the method is comprised in a method of manufacturing a flash memory device.

3. The method of claim 1, comprising removing the photo-resist layer and the spacers after etching the poly-silicon layer.

4. The method of claim 3, wherein said removing the photo-resist layer and the spacers comprises at least one of ashing and cleansing.

5. The method of claim 1, wherein said forming of the spacer oxidation film comprises atomic layer deposition.

6. The method of claim 1, wherein the spacer oxidation film comprises at least one of Al₂O₃, SiO₂, and HfO₂.

7. The method of claim 1, wherein the spacer oxide film is formed at a temperature less than approximately 120° C.

8. The method of claim 7, wherein the spacer oxide film is formed at a temperature less than approximately 100° C.

9. The method of claim 1, wherein said etching the poly-silicon layer comprises reactive ion etching.

10. The method of claim 1, wherein said etching the poly-silicon layer comprises forming an opening in the poly-silicon layer having a critical dimension less than approximately 90 nm.

11. The method of claim 1, wherein the poly-silicon layer is formed on the semiconductor substrate.

12. The method of claim 1, wherein the photo-resist layer is formed on the poly-silicon layer.

13. The method of claim 1, wherein the spacer oxide film is formed on the patterned photo-resist layer.

14. The method of claim 1, wherein the spacer oxide film is formed on the sidewalls.

15. The method of claim 1, wherein the spacers are formed on the sidewalls.

16. An apparatus comprising a patterned poly-silicon layer formed over a semiconductor substrate, wherein the patterned poly-silicon layer is formed by:
forming a photo-resist layer over a poly-silicon layer;
patterning the photo-resist layer to form at least one opening in the photo-resist layer;
forming a spacer oxidation film over the patterned photo-resist layer and over sidewalls of said at least one opening in the photo-resist layer;
etching the spacer oxidation film to form spacers over the sidewalls; and
etching the poly-silicon layer using the spacers as an etch mask to form said patterned poly-silicon layer.

17. The apparatus of claim 16, wherein the apparatus is a flash memory device.

18. The apparatus of claim 16, wherein said patterned poly-silicon layer comprises openings having a critical dimension less than approximately 90 nm.

19. The apparatus of claim 16, wherein the spacer oxide film is formed at a temperature less than approximately 120° C.

20. The apparatus of claim 16, wherein at least one of:
the poly-silicon layer is formed on the semiconductor substrate;
the photo-resist layer is formed on the poly-silicon layer;
the spacer oxide film is formed on the patterned photo-resist layer;
the spacer oxide film is formed on the sidewalls; and
the spacers are formed on the sidewalls.
